(19) United States
(12) Patent Application Publication
(10) Pub. No.: US 2005/0229854 A1
(43) Pub. Date: Oct. 20, 2005

(54) Method and apparatus for temperature change and control

(75) Inventor: Paul Moroz, Marblehead, MA (US)

Correspondence Address: PILLSBURY WINTHROP SHAW PITTMAN, LLP, P.O. BOX 10500, MCLEAN, VA, 22102, US

(73) Assignee: Tokyo Electron Limited, Tokyo (JP)

(21) Appl. No.: 10/824,643

(22) Filed: Apr. 15, 2004

(51) Int. Cl. C23C 16/00; C25B 9/00

(52) U.S. Cl. 118/725; 118/730; 204/298.09

(57) ABSTRACT

An apparatus for controlling the temperature of a substrate which includes a substrate table and a thermal assembly arranged in the substrate table and in thermal communication with a thermal surface of the substrate table. The thermal assembly includes a channel that carries a heat-transfer fluid. The apparatus further includes a fluid thermal unit which includes a first fluid unit configured to control the temperature of the heat-transfer fluid to a first temperature, a second fluid unit configured to control the temperature of the heat-transfer fluid to a second temperature, and an outlet flow control unit that is in fluid communication with the channel of the thermal assembly and the first and second fluid units. The outlet flow control unit is configured to supply the channel with a controlled heat transfer fluid, which includes at least one of the heat-transfer fluid having a first temperature, the heat transfer fluid having a second temperature or a combination thereof.

### BACKGROUND OF THE INVENTION

1. Field of the Invention

This invention relates to an apparatus and a method for controlling the temperature of a substrate. More particularly, this invention relates to an apparatus and a method for performing temperature change and temperature control of a substrate.

2. Description of Related Art

The demand for increasing throughput in semiconductors, displays and other types of substrate manufacturing is never-ending. In the semiconductor technology, for example, due to significant capital and operating expenses, even small improvements in the equipment or in the methods of using the equipment can lead to a significant financial advantage.

Many of the processes in substrate processing involve placing the substrate, such as a semiconductor wafer, on a substrate table of a processing system and processing the substrate. These processes generally include chemical processes, plasma induced processes, and etching and deposition processes, and depend on the temperature of the substrate.

### SUMMARY OF THE INVENTION

According to an aspect of the invention, there is provided an apparatus for controlling a temperature of a substrate, the substrate having a lower surface and an upper surface on which a substrate processing is performed. In an embodiment of the invention, the apparatus includes a substrate table having a thermal surface supporting the substrate lower surface and a thermal assembly arranged in the substrate table and in thermal communication with the thermal surface. The thermal assembly includes a channel that carries a heat-transfer fluid. The apparatus further includes a fluid thermal unit which includes a first fluid unit constructed and arranged to control the temperature of the heat-transfer fluid to a first temperature, a second fluid unit constructed and arranged to control the temperature of the heat transfer fluid to a second temperature, and an outlet flow control unit that is in fluid communication with the channel of the thermal assembly and the first and second fluid units. In this apparatus, the outlet flow control unit is constructed and arranged to supply the channel with a controlled heat transfer fluid, which includes at least one of the heat-transfer fluid having a first temperature, the heat transfer fluid having a second temperature or a combination thereof.

According to another aspect of the invention, there is provided a distributed temperature control system for controlling a temperature of a plurality of equipment, each of the plurality of equipment having a channel that carries a heat-transfer fluid. In an embodiment of the invention, the system includes a fluid thermal unit constructed and arranged to adjust a temperature of the heat-transfer fluid in each of the plurality of equipment. In this system, the thermal unit includes a first fluid unit constructed and arranged to control the temperature of the heat-transfer fluid to a first temperature, a second fluid unit constructed and arranged to control the temperature of the heat transfer fluid to a second temperature, and an outlet flow control unit that is in fluid communication with the channel of each of the plurality of equipment and the first and second fluid units. The outlet flow control unit of the thermal assembly is constructed and arranged to supply the channel of each of the plurality of equipment with the controlled heat transfer fluid, which includes at least one of the heat-transfer fluid having a first temperature, the heat transfer fluid having a second temperature or a combination thereof.

According to yet another aspect of the invention, there is provided a method of controlling a temperature of a substrate supported by a thermal surface of a substrate table, the substrate table including a fluid thermal assembly in thermal communication with the thermal surface. In an embodiment of the invention, the method includes adjusting a heat-transfer fluid of a first source of heat-transfer fluid to a first temperature and adjusting a heat-transfer fluid of a second source of heat-transfer fluid to a second temperature. The method further includes supplying the fluid thermal assembly with a controlled heat-transfer fluid including the heat-transfer fluid from the first source of heat-transfer fluid or the heat-transfer fluid from the second source of heat-transfer fluid or a combination thereof.

### BRIEF DESCRIPTION OF THE DRAWINGS

The above and other features of the present invention will be described in conjunction with the accompanying drawings in which:

FIG. 1 is a cross sectional representation of an apparatus according to an embodiment of the invention;

FIG. 2 is a cross-sectional representation of an apparatus according to an embodiment of the invention;

FIG. 3 is a cross-sectional representation of an apparatus according to an embodiment of the invention;

FIG. 4 is a cross-sectional representation of an apparatus according to an embodiment of the invention;

FIG. 5 is a schematic representation of a substrate processing system according to an embodiment of the invention;

FIG. 6 is a top view of the channel embedded in the substrate table according to an embodiment of the invention;

FIG. 7 is a schematic representation of a fluid thermal unit according to an embodiment of the invention;

FIG. 8 is a schematic representation of the first and the second fluid units according to an embodiment of the invention;

FIG. 9 is a schematic representation of the first and the second fluid units according to an embodiment of the invention;

FIG. 10 is a schematic representation of a fluid thermal unit according to an embodiment of the invention;

FIG. 11 is a schematic representation of a fluid thermal unit according to an embodiment of the invention;

FIG. 12 is a schematic representation of an outlet flow control unit according to an embodiment of the invention;

FIG. 13 is a schematic representation of a fluid thermal unit according to an embodiment of the invention;

FIG. 14 is a schematic representation of a fluid thermal unit according to an embodiment of the invention;

FIG. 15 is a schematic representation of a fluid thermal unit according to an embodiment of the invention; and

FIG. 16 is a schematic representation of a distributed temperature control system according to an embodiment of the invention.

### DETAILED DESCRIPTION OF SEVERAL EMBODIMENTS OF THE INVENTION

In the following description, in order to facilitate a thorough understanding of the invention and for purposes of explanation and not limitation, specific details are set forth, such as a particular geometry of the substrate table and various elements arranged in the substrate table. However, it should be understood that the invention may be practiced in other embodiments that depart from these specific details.

The present invention provides an apparatus and a method for temperature change and temperature control of any type of equipment, including that used for materials processing, such as etching or deposition. More particularly, the apparatus and the method may be used, in an embodiment of the invention, for temperature change and control of the thermal part or upper body of a substrate table on which a substrate is disposed.

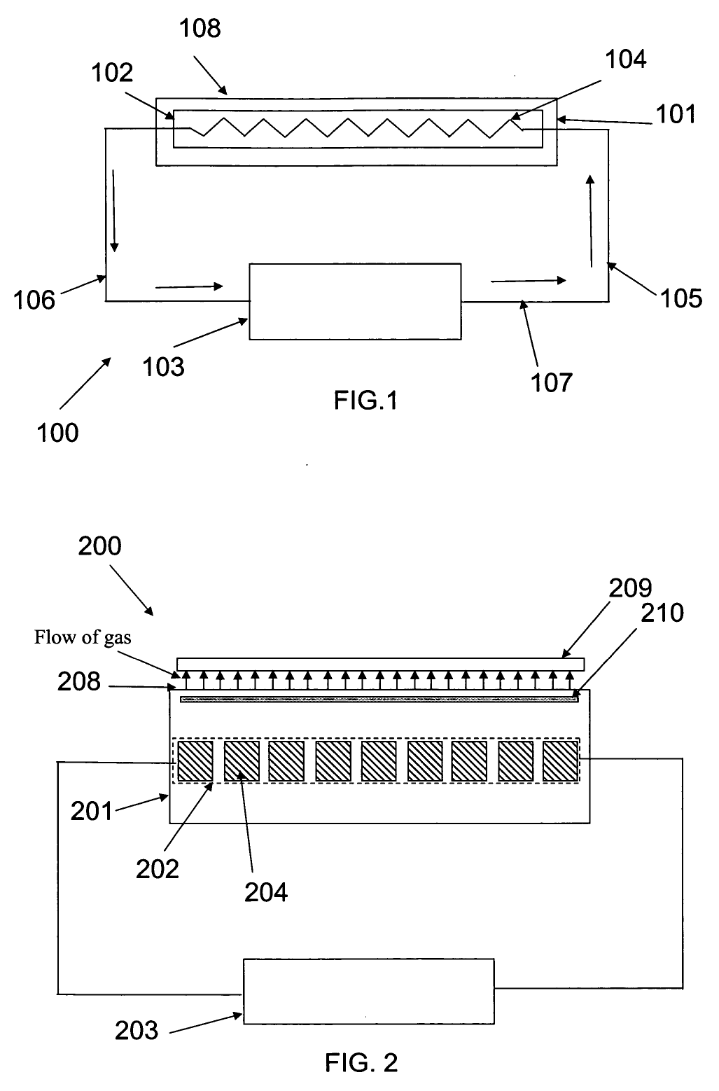

FIG. 1 is a simplified representation of an apparatus according to an embodiment of the invention. In this embodiment of the invention, apparatus 100 includes block 101, thermal assembly 102 and fluid thermal unit 103. Block 101 represents any part of an equipment that has to be cooled or heated such as, for example, a substrate holder. As can be seen in FIG. 1, thermal assembly 102 is arranged in block 101 and includes channel 104 that carries a heat-transfer fluid 105. Channel 104 is in fluid communication with fluid thermal unit 103 through conduits 106 and 107. In the embodiment of the invention represented in FIG. 1, fluid thermal unit 103 is constructed and arranged to supply channel 104 with a controlled heat-transfer fluid having a desired temperature. In FIG. 1, thermal assembly 102 is in thermal communication with a thermal surface 108 of block 101 and is positioned within block 101 such that control of the temperature of thermal surface can be performed. In the embodiment of the present invention shown in FIG. 1, heating or cooling of the thermal surface 108 is by direct thermal conduction, from the heat-transfer fluid to the thermal surface 108, via channel 104 and thermal assembly 102.

FIG. 2 represents an apparatus for controlling a temperature of a substrate according to an embodiment of the invention. In FIG. 2, apparatus 200 includes a substrate table 201 on which a substrate 209 is disposed. Apparatus 200 also includes a thermal assembly 202 that is configured to control the temperature of the thermal surface 208 of substrate table 201. Apparatus 200 further includes an electrode 210 configured to electrostatically clamp substrate 209 on thermal surface 208 during substrate processing. In this embodiment of the invention, a backside flow, such as helium, is provided to enhance the thermal conductivity between substrate table 201 and substrate 209. The actual distance between substrate 209 and substrate table 201 may be very small, e.g. in a micron range, in an embodiment of the invention.

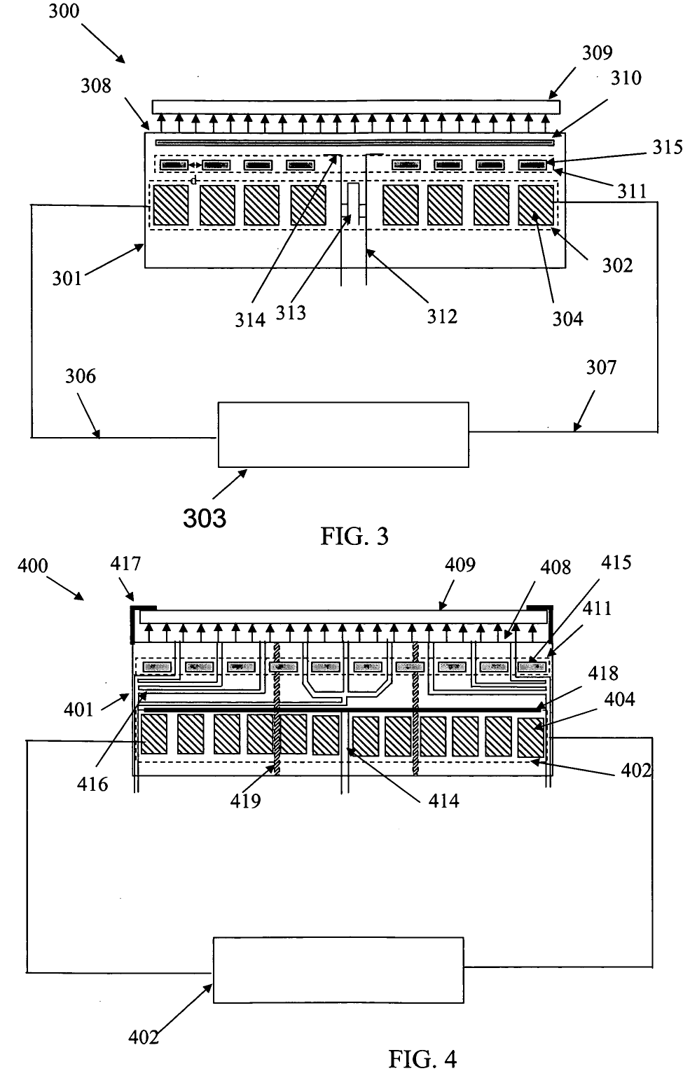

Referring now to FIG. 3, this figure illustrates an apparatus for controlling a temperature of a substrate according to an embodiment of the invention. In this embodiment of the invention, RF power is applied directly to the upper body of the substrate table 301. As can be seen in FIG. 3, apparatus 300 includes thermal assembly 302 and second thermal assembly 311 that is in thermal communication with the thermal surface 308. In the embodiment of the invention represented in FIG. 3, second thermal assembly includes a plurality of thermoelectric modules 315 such as, for example, Peltier devices, which are configured to quickly change the temperature of thermal surface 308. Thermal assembly 302 is arranged in substrate table 301 and includes channel 304 that carries a heat-transfer fluid. Apparatus 300 also includes an electrode 310 that is configured to electrostatically clamp the substrate 309 during substrate processing. A flow of gas is likewise provided to enhance the thermal conductivity between substrate table 301 and substrate 309. In this embodiment of the invention, thermal assembly 311 includes a plurality of thermoelectric modules such as, for example, Peltier modules.

In the embodiment of the invention represented in FIG. 3, the RF power is directly supplied to the upper body of substrate table 301 via an RF assembly including RF cable 312, RF feeder 313 and RF connector 314. Although not shown in FIG. 3, RF cable 312 may be connected to an RF power generator and an RF match circuit. In FIG. 3, the RF assembly extends through first and second thermal assemblies, 302 and 311, in order to deliver the RF power close to thermal surface 308 where substrate 309 is disposed.

FIG. 4 illustrates an apparatus including an RF power assembly according to another embodiment of the invention. Similarly to FIG. 3, apparatus 400 includes a substrate table 401 in which a first thermal assembly 402 and a second thermal assembly 411 are arranged. Apparatus 400 also includes thermal surface 408, which supports substrate 409, and gas line assembly 416 that provides backside pressure to substrate 409. In FIG. 4, the gas lines of the gas line assembly 416 are disposed between the plurality of thermoelectric modules 415 of the second thermal assembly 411 and channel 404. In this embodiment of the invention, substrate 409 is mechanically clamped to the thermal surface with clamping assembly 417. Apparatus 400 further includes an RF power assembly including RF connector 414 coupled to RF power plate 418. In the embodiment of the invention shown in FIG. 4, the RF plate is arranged between first and second thermal assemblies, 402 and 411. In this configuration, the material constituting RF power plate 418 is selected so as not to form a thermal barrier to second thermal assembly 411. In another embodiment, power plate 418 may be disposed underneath second thermal assembly 411. In the embodiment of the invention represented in FIG. 4, placing and removing substrate 409 is done by pins 419 arranged in substrate table 401 and through first and second thermal assemblies 402 and 411.

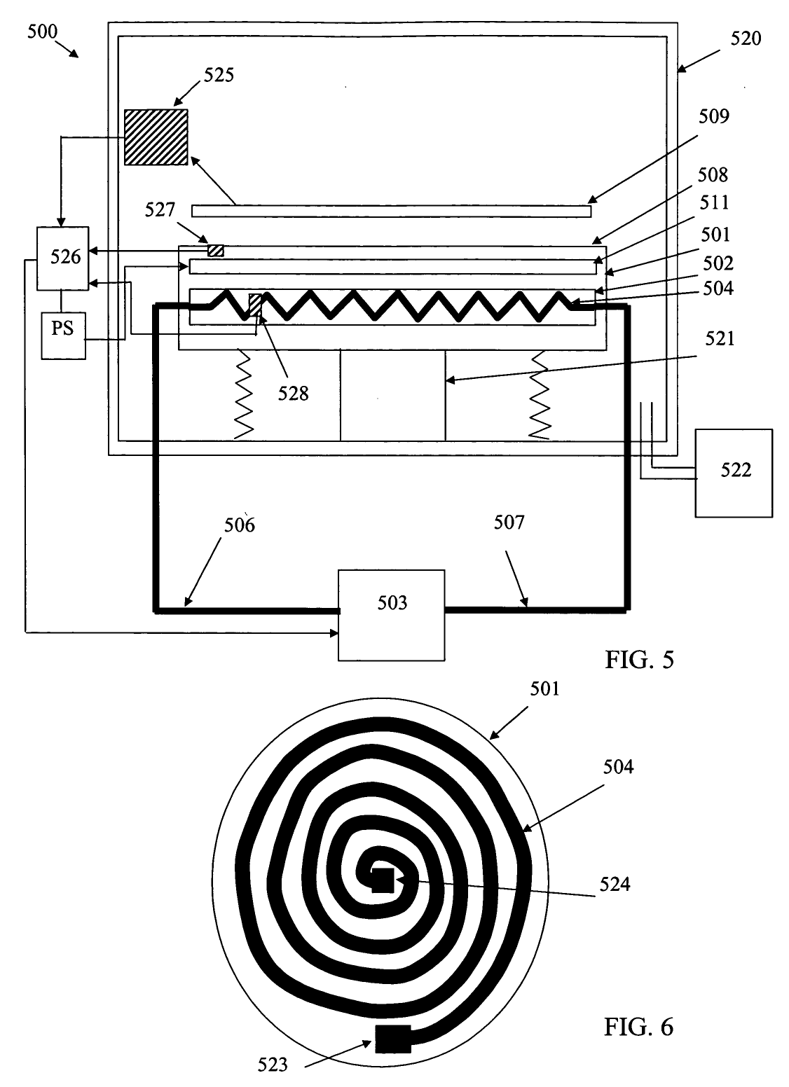

Referring now to FIG. 5, an exemplary embodiment of a substrate processing system capable of controlling the temperature of a substrate during substrate processing will now be explained.

Substrate processing system 500 includes vacuum chamber 520 in which substrate table 501 is arranged. Similarly to the embodiment shown in FIG. 4, substrate table 501 includes first thermal assembly 502, second thermal assembly 511 and thermal surface 508, on which substrate 509 is disposed. Substrate processing system 500 further includes a moving assembly 521, configured to vertically move substrate table 501 within processing chamber 520, and pumping system 522 constructed and arranged to maintain a desired pressure inside chamber 520. In the embodiment illustrated in FIG. 5, second thermal assembly 511 may be identical to thermal assembly 311 shown in FIG. 3 and may include a plurality of thermoelectric modules such as, for example, Peltier devices, which are configured to quickly change the temperature of thermal surface 508. In FIG. 5, thermal assembly 502 includes channel 504, which carries a heat-transfer fluid and which is in fluid communication with fluid thermal unit 503. In this embodiment of the invention, the temperature of the heat-transfer fluid within channel 504 and/or conduits 506 and 507 is controlled by fluid thermal unit 503. In another embodiment of the invention, second thermal assembly 511 may include a resistive heater connected to a variable power source. In either embodiment, heating or cooling is achieved by direct thermal conduction, from the thermoelectric modules, or the resistive heater, to thermal surface 508, via first thermal assembly 511.

It should be understood that channel 504 that carries the heat-transfer fluid may have different shapes. In an embodiment of the invention, channel 504 has a spiral shape and is designed to thermally cover a substantial area of thermal surface 508. This embodiment of the invention is depicted in FIG. 6, which represents a schematic top view of channel 504 embedded within substrate table 501. As can be seen in this figure, channel 504 includes inlet 523 and outlet 524 that are in fluid communication with fluid thermal unit 503 through conduits 506 and 507. In FIGS. 5 and 6, location of the channel 504 relative to thermal surface 508 is such that efficient heat transfer to and uniform temperature distribution on the thermal surface can be achieved. In an embodiment of the invention, the distance separating channel 504 from thermal surface 508 is in the range of approximately 1 to 30 mm.

It should also be understood that substrate processing system 500 shown in FIG. 5 may be a plasma processing system, an etch system, a Chemical Vapor Deposition (CVD) system, a plasma enhanced chemical vapor deposition (PECVD) system, a Physical Vapor Deposition (PVD) system, an ionized physical vapor deposition (iPVD) system, or a non-plasma processing system such as a track system, a chemical oxide removal (COR) system, or more generally, any type of system in which it is desirable to control the temperature of the substrate during substrate processing. In a plasma processing configuration, for example, substrate processing system 500 may include a plasma generating system and a gas source configured to introduce gas into chamber 520 for creating a processing plasma. In operation, substrate 509 may be clamped to substrate table 501 via an electrostatic, a suction or a mechanical device. Generally, for chemical and/or plasma processing, substrate table 501 and substrate 509 are placed in chamber 520, where a reduced pressure is attained via pumping system 522. Although not shown in the embodiment represented in FIG. 5, substrate processing system 500 may also include additional process gas lines entering processing chamber 520, a Radio Frequency (RF) power system, a second electrode (that could be used for a capacitively-coupled type system) or an RF coil (that could be used for an inductively coupled type system).

During processing of substrate 509, adjustment and control of the temperature of the thermal surface may be achieved via wafer temperature measurement system (or sensor) 525 arranged in chamber 520. In an embodiment of the invention, temperature measurements of substrate 509 are taken by wafer temperature measurement system 525 and input into wafer temperature control system 526. In case the temperature needs to be adjusted, control system 526 commands the fluid thermal unit 503 to adjust the temperature, volume and flow rate of the heat-transfer fluid supplied to channel 504. As can be seen in FIG. 5, measurements of the temperature of substrate 509 may be performed using optical techniques, such as an optical fiber thermometer commercially available from Advanced Energies, Inc. (1625 Sharp Point Drive, Fort Collins, Colo., 80525), Model No. OR2000F capable of measurements from 50 to 2000 C and an accuracy of plus or minus 1.5 C, or a band-edge temperature measurement system as described in pending U.S. patent application Ser. No. 10/168,544, filed on Jul. 2, 2002, the contents of which are incorporated herein by reference in their entirety. In another embodiment of the invention, measurements of the substrate temperature may be done with thermocouples 527 embedded in various parts of substrate table 501. In this latter configuration, the thermocouples may be directly connected to substrate temperature control system 526. In yet another embodiment of the invention, the control of the temperature of substrate 509 may be done by monitoring the temperature of the fluid via a temperature probe 528 embedded within channel 504 and/or conduits 506 and 507 and coupled to the temperature control system 526. In this latter scenario, the temperature control system 526 may directly estimate the temperature of the substrate 509 via the temperature provided by probe 528. It should be understood that any combination of these sensors can be employed to control the temperature of the thermal surface.

As can also be seen in FIG. 5, temperature control system 526 may also be configured to control second thermal assembly 511. In case second thermal assembly includes a resistive heater or a plurality of thermoelectric modules, temperature control system 526 may directly be coupled to a power source PS that supplies second thermal assembly 511 with the required power.

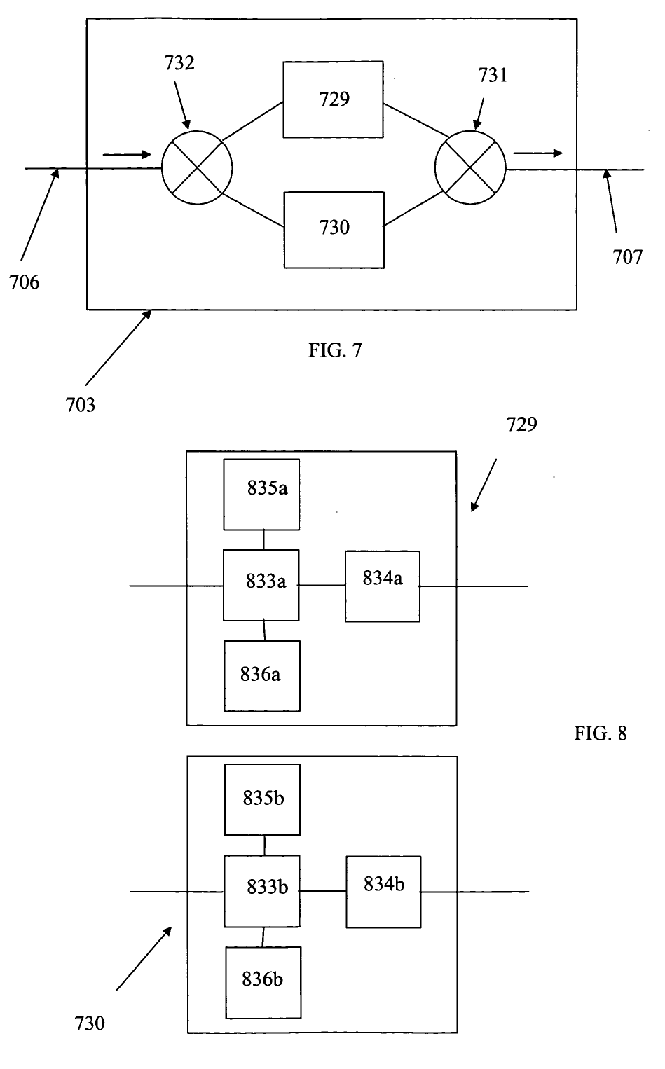

Referring now to FIG. 7, a schematic representation of a fluid thermal unit according to an embodiment of the invention will now be described.

In this embodiment of the invention, fluid thermal unit 703 includes a first fluid unit 729 (or a first source of heat-transfer fluid) constructed and arranged to control/adjust the temperature of the heat-transfer fluid to a first temperature and a second thermal unit 730 (or a second source of heat-transfer fluid) constructed and arranged to control/adjust the temperature of the heat-transfer fluid to a second temperature. This second temperature may be equal to or different from the first temperature. Fluid thermal unit 703 further includes an outlet flow control unit 731 which is in fluid communication with the channel of the thermal assembly through conduit 707, and with first and second fluid units 729 and 730. In the embodiment of the invention shown in FIG. 7, outlet flow control unit 731 is constructed and arranged to supply the channel of the thermal assembly with a controlled heat-transfer fluid including at least one of the heat-transfer fluid having a first temperature, the heat-transfer fluid having a second temperature or a combination thereof. In an embodiment of the invention, outlet flow control unit 731 may control the flow rate and volume of controlled heat-transfer fluid supplied to the thermal assembly in accordance with the instructions received from the temperature control system. In the embodiment of the invention illustrated in FIG. 7, fluid thermal unit 703 further includes an inlet distribution unit 732 that is in fluid communication with the channel of the thermal assembly through conduit 706 and with the first and second fluid units 729 and 730. Inlet distribution unit 732 is constructed and arranged to control a volume or flow rate of controlled heat transfer fluid flowing to the first fluid unit 729 and a volume or flow rate of controlled heat transfer fluid flowing to the second fluid unit 730.

Referring now to FIG. 8, each of the first and second fluid units 729 and 730, according to an embodiment of the invention, includes a storage fluid tank, 833a and 833b, a pump, 834a and 834b, a heater, 835a and 835b, and a cooler, 836a and 836b. Storage fluid tanks 833a and 833b are configured to store the controlled heat-transfer fluid flowing from the inlet distribution unit. Units 729 and 730 may also include, in an embodiment of the invention, level sensors that are configured to detect a volume of heat-transfer fluid in each of these tanks. The heaters and the coolers are configured to adjust the temperature of the heat-transfer fluid stored in tanks 833a and 833b to a first temperature and to a second temperature respectively. The pumps 834a and 834b supply the outlet flow control unit with the heat-transfer fluid having a first temperature and with the heat-transfer fluid having a second temperature. In an embodiment of the invention, storage fluid tank 833a-b, pump 834a-b, heater 835a-b and cooler 836a-b, may be controlled by the temperature control system.

In an embodiment of the invention, it may be desirable that the heat-transfer fluid include electrically non-conductive liquids such as, for example, Fluorinert™ or Galden™. In that way, the heat-transfer fluid will not be conductive in the presence of the radio-frequency power supplied to the substrate table to generate the plasma.

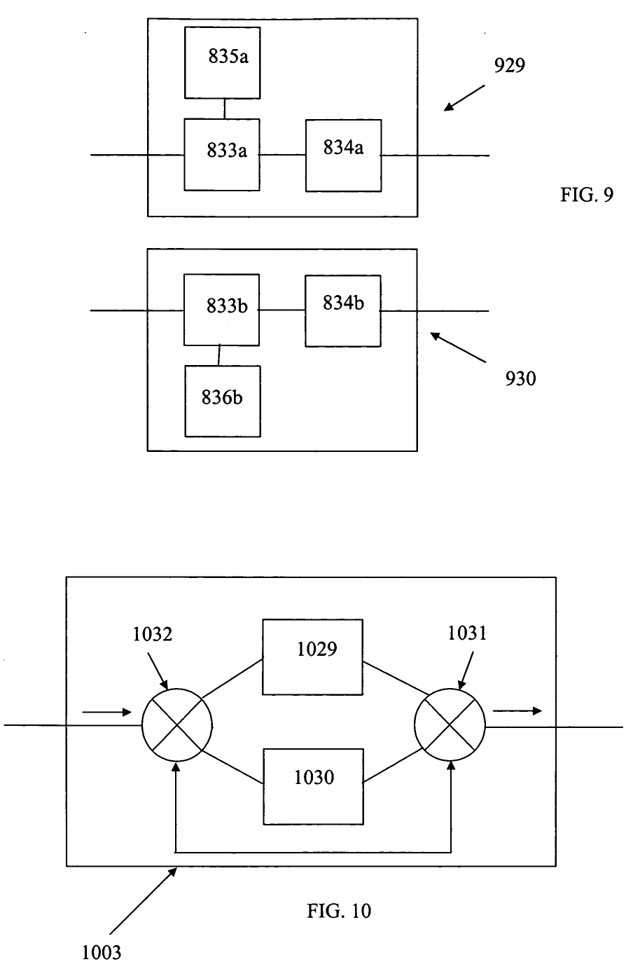

In an embodiment of the invention, the first fluid unit may be a hot fluid unit 929 while the second fluid unit may be a cold fluid unit 930 or vice versa. In such a configuration, it may be possible to suppress the cooler in the first fluid unit and the heater in the second fluid unit (or vice versa). This embodiment of the invention is schematically represented in FIG. 9.

In the embodiment of the invention shown in FIG. 7, the outlet flow control unit 731 and the inlet distribution unit 732 may be operated independently of each other. In such a configuration, the volume of heat-transfer fluid leaving the first and second fluid units may be different from the volume of controlled heat-transfer fluid returning to these units. In an embodiment of the invention, the volume of heat-transfer fluid returning to the first unit may be much larger than the volume of heat-transfer fluid returning to the second unit. In this way, a large volume of fluid having a first temperature may readily be available for future use. Such a regime of operation may be advantageous to anticipate large temperature changes (in a cooling phase or a heating phase). In this mode of operation, it may be possible to provide faster heating of the substrate during a heating phase. Conversely, it may be possible to store large volumes of heat-transfer fluid in the second unit in anticipation of a cooling phase.

It should be understood, however, that the outlet flow control unit 731 and the inlet distribution unit 732 may also be operated in a cooperative relationship. Such a parallel mode of operation is schematically illustrated in FIG. 10, which represents a schematic configuration of the fluid thermal unit 1003. In this embodiment of the invention, the amount of fluid leaving the first and second fluid units, 1029 and 1030, is substantially the same as the amount of fluid returning to these units.

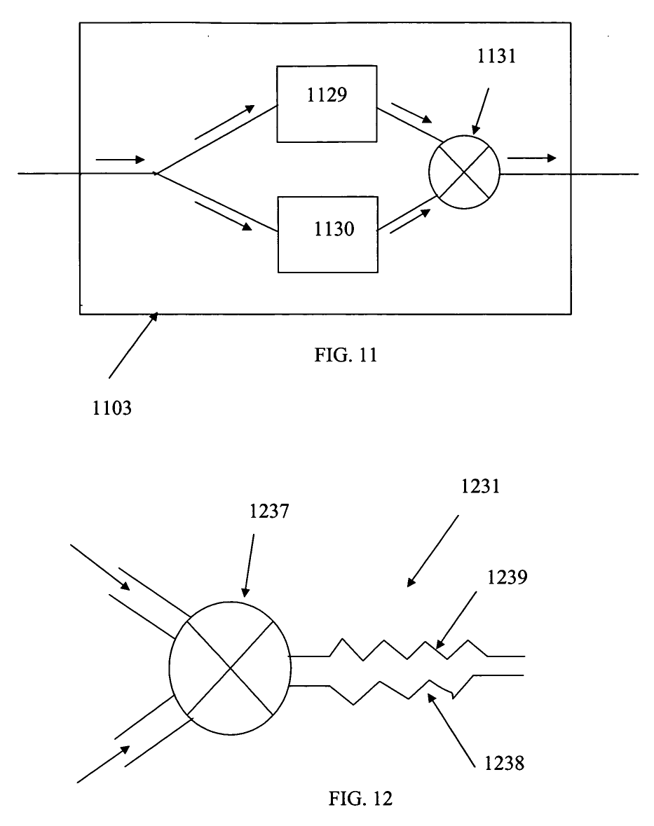

In another embodiment of the invention, the fluid thermal unit is configured such that the amount of heat-transfer fluid in each of the units remains substantially constant. In this configuration, the inlet distribution unit may be omitted. This mode of operation of the fluid thermal unit is illustrated in FIG. 11.

The outlet flow control unit represented in the different embodiments of the present invention may include a mixer that is configured to supply the channel with a controlled heat transfer fluid including one of the heat-transfer fluid having a first temperature, the heat transfer fluid having a second temperature or a combination thereof. In this embodiment of the invention, the mixer may include a mixing tank and a mixing device configured to mix the heat-transfer fluid having a first temperature with the heat-transfer fluid having a second temperature. In another embodiment of the invention, the mixer 1231 may include a pump 1237 and a mixing flow chamber 1238 having a mixing flow surface 1239. In this embodiment of the invention, the heat-transfer fluid having a first temperature and the heat-transfer fluid having a second temperature are directed to a chamber similar to the one illustrated in FIG. 12. Mixing of the two fluids is performed in this embodiment by mechanical mixing within the mixing flow chamber 1238.

In another embodiment of the invention, the outlet flow control unit may include selector valves that are configured to selectively send the heat-transfer fluid having the first temperature and the heat-transfer fluid having a second temperature. This embodiment of the invention is represented in FIG. 13, which depicts a fluid thermal unit 1303 including first and second fluid units 1329 and 1330. In FIG. 13, fluid thermal unit 1303 includes an outlet flow control unit 1331 comprising a first outlet selector valve 1340 and a second outlet selector valve 1341. Fluid thermal unit 1303 also includes an inlet distribution unit 1332 comprising a first inlet selector valve 1342 and a second inlet selector valve 1343. In this embodiment of the invention, the first and second outlet selector valves and the first and second inlet selector valves control the flow of heat-transfer fluid in and out of units 1329 and 1330.

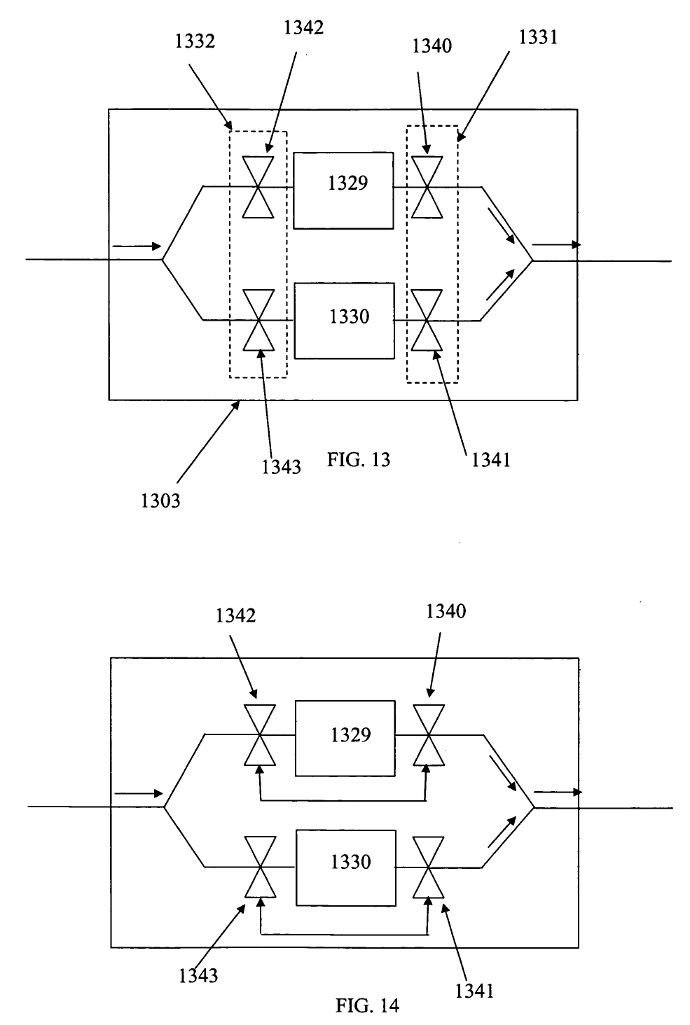

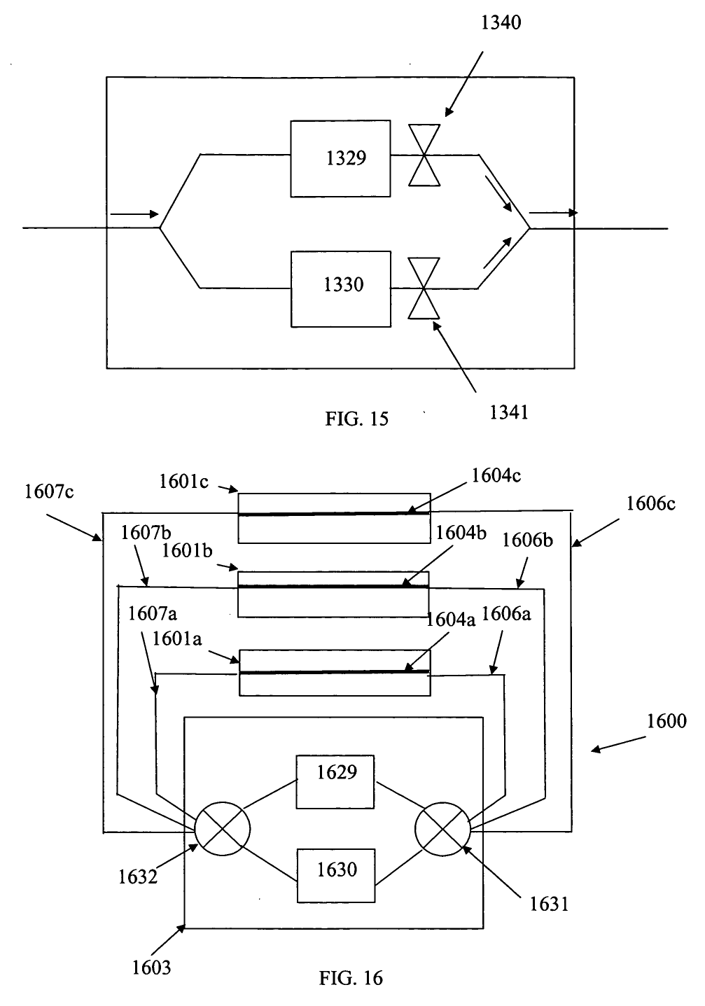

In operation, the inlet and outlet valves may be operated independently from each other or in a cooperative relationship. This latter configuration, illustrated in FIG. 14, may ensure that the amount of heat-transfer fluid remains substantially the same in the fluid thermal units 1329 and 1330. In another embodiment of the invention, fluid units 1329 and 1330 may be designed such that they can only contain a constant and specified amount of heat-transfer fluid. In such a case, the inlet distribution unit may be omitted. This embodiment of the invention is shown in FIG. 15.

Operation of the thermal unit according to an embodiment of the invention will now be explained.

In case the temperature of the controlled heat-transfer fluid lays in the range between T3 and T4, where T3>T4, the first fluid unit of the fluid thermal unit may then set the first temperature to T1≧T3 while the second fluid unit may set the second temperature to T2≦T4. During the initial stage of a heating phase, the outlet flow control unit may be configured to supply the thermal assembly with the heat-transfer fluid having the first temperature T1. This may allow for a faster heating of the substrate. Then, when the temperature of the substrate gets closer to the aimed temperature T3, the outlet flow control unit may be controlled to slowly release the heat-transfer fluid having the second temperature T2 (or a mixture of these two fluids). In such a mode of operation, it may be possible to rapidly change the temperature of the thermal surface while providing at the same time a smooth transition between the actual temperature of the thermal surface and the target temperature.

In the cooling phase, the thermal unit may be operated in a similar manner. That is, the outlet flow control unit may be configured to supply the thermal assembly with the heat-transfer fluid having a second temperature T2 during the initial stage of the cooling process. With this mode of operation, it may be possible to quickly reach the target temperature T4. Then, when the substrate temperature gets closer to the target temperature, the outlet flow control unit of the fluid thermal unit may slowly start supplying the thermal assembly with the heat-transfer fluid having the first temperature T1 (or with a mixture of these fluids). In this way, it may be possible to rapidly change the temperature of the thermal surface while providing at the same time a smooth transition between the actual temperature of the thermal surface and the target temperature.

In order to obtain faster temperature changes, the fluid thermal unit may, in an embodiment of the invention, be configured to overheat and/or overcool the heat-transfer fluid. In this embodiment of the invention, the overheated fluid has a temperature T1>T3, and the overcooled fluid has a temperature T2<T4. The larger the difference is between T1 and T3, the faster heating will occur. Similarly, the larger the difference is between T2 and T4, the faster cooling will occur.

In anticipation of a heating phase, the fluid thermal unit may be configured, in an embodiment of the invention, to store large amounts of heat-transfer fluid in the storage tank of the first fluid unit. The storage of heat-transfer fluid having a first temperature (hot temperature in the present case) would be done at the expense of the storage tank of the second fluid unit. In this embodiment of the invention, a larger amount of hot heat-transfer fluid (i.e. heat-transfer fluid having a first temperature) may be useful to provide faster heating of the substrate, especially when the thermal mass of the substrate table is significant.

A similar approach may be pursued in anticipation of a cooling phase. In that case, the fluid thermal unit may be configured to store a larger amount of heat-transfer fluid in the second fluid unit (that works in cooling mode).

In another embodiment of the invention, the fluid thermal unit may be configured to provide faster heating/cooling by increasing the flow rate of the controlled heat-transfer fluid supplied to the channel. In this mode of operation, a steeper heating or cooling front may be obtained.

It should be understood that the different elements of the fluid thermal unit may be controlled by the temperature control system. This temperature control system may include electronic/computer units that control the different parts of the outlet flow control unit, the inlet distribution unit and the first and second fluid units on the basis of data collected by temperature probes. The temperature control system may also be configured, in an embodiment of the invention, to directly monitor the temperature of the heat-transfer fluid in the first and second thermal units. In another embodiment of the invention, the temperature control system may be configured to read executable instructions of a programmed process scenario (of temperature variation).

FIG. 16 shows a schematic representation of a distributed temperature control system 1600 according to an embodiment of the invention. In this embodiment of the invention, the distributed temperature control system is configured to control a temperature of a plurality of equipments such as, for example, substrate tables.

Referring now in more detail to FIG. 16, distributed system 1600 includes a fluid thermal unit 1603 that is constructed and arranged to adjust a temperature of the heat-transfer fluid supplied to each of the equipment 1601a, 1601b and 1601c. Each of these equipment is in fluid communication with the thermal unit 1603 via conduits 1606a-c and 1607a-c and via channels 1604a-c disposed within the equipment. In this embodiment of the invention, heating of each of these equipment is done by thermal conduction from the heat-transfer fluid via channels 1604a-c.

As can be seen in FIG. 16, fluid thermal unit 1603 includes a first fluid unit 1629 constructed and arranged to control the temperature of the heat-transfer fluid to a first temperature and a second fluid unit 1630 constructed and arranged to control the temperature of the heat-transfer fluid to a second temperature. Fluid thermal unit 1603 also includes an outlet flow control unit 1631 that is in fluid communication with the first and second fluid units 1629 and 1630, and with the channels 1604a-c of each of the equipment 1601a-c. In this embodiment of the invention, the outlet flow control unit 1631 is constructed and arranged to supply the channel of each of these equipment with a controlled heat transfer fluid including at least one of the heat-transfer fluid having a first temperature, the heat transfer fluid having a second temperature or a combination thereof.

In the embodiment of the invention shown in FIG. 16, fluid thermal unit 1603 also includes an inlet distribution unit 1632 that is in fluid communication with the first and second fluid units 1629 and 1630 and with each of the channels 1604a-c. In particular, the inlet distribution unit 1632 is constructed and arranged to control a volume of controlled heat transfer fluid flowing to the first fluid unit and a volume of controlled heat transfer fluid flowing to the second fluid unit.

The distributed temperature control system 1600 enables one to efficiently control a temperature of each of these equipment. In operation, the fluid thermal unit 1603 may be coupled to a temperature control system, which may be similar to the one represented in the embodiment of the invention shown in FIG. 5. Temperature measurements taken by the temperature measurement system may be input into the temperature control system which in turn may direct the thermal unit to supply each of the channels with a controlled heat-transfer fluid having an appropriate temperature. In this way, it may be possible to independently control each of these equipment.

In an embodiment of the invention, the fluid thermal unit 1603 may be located outside a clean room. In another embodiment of the invention, only the fluid unit acting as the refrigerating unit may be located outside the clean room and/or apart from the other fluid unit. These configurations may be desirable when the type of refrigeration used to cool the heat-transfer fluid and the conditions of the clean room are not compatible.

While a detailed description of presently preferred embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

1. An apparatus for controlling a temperature of a substrate, the substrate having a lower surface and an upper surface on which a substrate processing is performed, the apparatus comprising:
a substrate table having a thermal surface supporting the substrate lower surface;
a thermal assembly arranged in the substrate table and in thermal communication with the thermal surface, the thermal assembly comprising a channel that carries a heat-transfer fluid; and
a fluid thermal unit constructed and arranged to adjust a temperature of the heat-transfer fluid, the fluid thermal unit comprising:
a first fluid unit constructed and arranged to control the temperature of the heat-transfer fluid to a first temperature;
a second fluid unit constructed and arranged to control the temperature of the heat transfer fluid to a second temperature; and
an outlet flow control unit that is in fluid communication with the channel of the thermal assembly and the first and second fluid units, the outlet flow control unit being constructed and arranged to supply the channel with a controlled heat transfer fluid comprising at least one of the heat-transfer fluid having a first temperature, the heat transfer fluid having a second temperature or a combination thereof.

2. An apparatus as recited in claim 1, further comprising an inlet distribution unit that is in fluid communication with the channel of the thermal assembly and the first and second fluid units, the inlet distribution unit being constructed and arranged to control a volume, a flow rate, or combination thereof of controlled heat transfer fluid flowing to the first fluid unit and a volume, a flow rate, or combination thereof of controlled heat transfer fluid flowing to the second fluid unit.

3. An apparatus as recited in claim 1, wherein each of the first and second fluid units comprises a storage fluid tank, a pump, a heater and a cooler.

4. An apparatus as recited in claim 1, further comprising a temperature control system constructed and arranged to control a supply of the controlled heat-transfer fluid based upon a temperature of one of the substrate surface, the thermal surface and the controlled heat-transfer fluid in the channel.

5. An apparatus as recited in claim 1, further comprising a temperature sensor constructed and arranged to detect a temperature of one of the thermal surface, the substrate surface and the controlled heat-transfer fluid in the channel.

6. An apparatus as recited in claim 1, wherein each of the first and second fluid units comprises a temperature sensor to detect a temperature of the heat-transfer fluid inside the unit.

7. An apparatus as recited in claim 3, wherein each of the first and second fluid units further comprises a level sensor configured to detect a volume of heat-transfer fluid in the storage fluid tank.

8. An apparatus as recited in claim 2, wherein the outlet flow control unit is in a cooperative relationship with the inlet distribution unit such that a volume of heat-transfer fluid located in each of the first and second units is substantially constant.

9. An apparatus as recited in claim 1, wherein the outlet flow control unit comprises a first valve constructed and arranged to allow the heat-transfer fluid having a first temperature to flow from the first fluid unit and a second valve constructed and arranged to allow the heat-transfer fluid having a second temperature to flow from the second fluid unit.

10. An apparatus as recited in claim 1, wherein the first fluid unit comprises a storage fluid tank and a heater and wherein the second fluid unit comprises a storage fluid tank and a cooler.

11. An apparatus as recited in claim 1, wherein one of the first fluid unit and the second fluid unit is located remotely from the substrate table.

12. An apparatus as recited in claim 1, wherein the thermal surface is located within a vacuum process chamber.

13. An apparatus as recited in claim 12, wherein the vacuum process chamber is a plasma process chamber.

14. An apparatus as recited in claim 1, further comprising an electrode arranged in the substrate table and configured to electrostatically clamp the substrate to the thermal surface of the substrate table.

15. An apparatus as recited in claim 1, further comprising a second thermal assembly in thermal communication with the thermal surface.

16. An apparatus as recited in claim 15, wherein the second thermal assembly comprises a plurality of thermoelectric modules.

17. An apparatus as recited in claim 1, further comprising a gas conduit passing through the substrate table and having a first end open to the thermal surface and a second end opposite the first end such that a gas can flow through said conduit and provide backside pressure to the substrate.

18. An apparatus as recited in claim 1, further comprising an RF power plate arranged in the substrate table and an RF power connector that connects the RF power plate to an RF power supply.

19. An apparatus as recited in claim 1, further comprising at least one pin constructed and arranged to place and remove the substrate on the thermal surface wherein the at least one pin passes through the thermal assembly.

20. An apparatus as recited in claim 1, further comprising mechanical or suction clamps to clamp the substrate.

21. An apparatus as recited in claim 4, wherein the temperature control system is further configured to prevent temperature overshooting during fast heating or fast cooling of the thermal surface.

22. An apparatus as recited in claim 21, wherein during fast heating the temperature of the thermal surface increases quickly and then slowly when the temperature of the thermal surface is substantially close to a desired temperature.

23. An apparatus as recited in claim 21, wherein during fast cooling the temperature of the thermal surface decreases quickly and then slowly when the temperature of the thermal surface is substantially close to a desired temperature.

24. A distributed temperature control system for controlling a temperature of a plurality of equipment, each of the plurality of equipment having a channel that carries a heat-transfer fluid, the system comprising:
a fluid thermal unit constructed and arranged to adjust a temperature of the heat-transfer fluid for each of the plurality of equipment, the thermal unit comprising:
a first fluid unit constructed and arranged to control the temperature of the heat-transfer fluid to a first temperature;
a second fluid unit constructed and arranged to control the temperature of the heat transfer fluid to a second temperature; and
an outlet flow control unit that is in fluid communication with the channel of each of the plurality of equipment and the first and second fluid units, the outlet flow control unit being constructed and arranged to supply the channel of each of the plurality of equipments with the controlled heat transfer fluid comprising at least one of the heat-transfer fluid having a first temperature, the heat transfer fluid having a second temperature or a combination thereof.

25. A method of controlling a temperature of a substrate supported by a thermal surface of a substrate table, the substrate table including a fluid thermal assembly in thermal communication with the thermal surface, the method comprising:
adjusting a heat-transfer fluid of a first source of heat-transfer fluid to a first temperature;
adjusting a heat-transfer fluid of a second source of heat-transfer fluid to a second temperature; and
supplying the fluid thermal assembly with a controlled heat-transfer fluid comprising the heat-transfer fluid from the first source of heat-transfer fluid or the heat-transfer fluid from the second source of heat-transfer fluid, or a combination thereof.

26. A method as recited in claim 25, wherein during an initial stage of a heating or a cooling phase the supplying comprises supplying the fluid thermal assembly with only the heat-transfer fluid from the first source of heat-transfer fluid or the heat-transfer fluid from the second source of heat-transfer fluid.

27. A method as recited in claim 26, further comprising overheating or overcooling the heat-transfer fluid from the first source of heat-transfer fluid or the heat-transfer fluid from the second source of heat-transfer fluid.

28. A method as recited in claim 25, wherein in anticipation of a heating phase or a cooling phase the method further comprises increasing an amount of heat-transfer fluid in the first source of heat-transfer fluid or the second source of heat-transfer fluid.

29. A method as recited in claim 26, wherein the method further comprises increasing a flow rate of the controlled heat-transfer fluid supplied to the fluid thermal assembly.

30. A method as recited in claim 25, further comprising detecting a temperature of the controlled heat-transfer fluid, the thermal surface or the substrate and controlling the supplying based on the detected temperature.

31. A method as recited in claim 25, further comprising controlling the supplying on the basis of readable instructions of a programmed process scenario.
